(19) United States
(12) Patent Application Publication
(10) Pub. No.: US 2025/0218927 A1
(43) Pub. Date: Jul. 3, 2025

(54) FLAT PACKAGE

(71) Applicant: PANJIT INTERNATIONAL INC., Kaohsiung City (TW)

(72) Inventors: YUNG-HUI WANG, Kaohsiung City (TW); CHUNG-HSIUNG HO, Kaohsiung City (TW); WEI-TING CHEN, Taipei City (TW)

(21) Appl. No.: 18/588,426

(22) Filed: Feb. 27, 2024

(30) Foreign Application Priority Data
Dec. 28, 2023 (TW) 112151355

(51) Int. Cl. H01L 23/498; H01L 23/00; H01L 23/31

(52) U.S. Cl. CPC H01L 23/49894; H01L 23/3107; H01L 24/06; H01L 24/14; H01L 2224/0603; H01L 2224/1403

(57) ABSTRACT

A flat package includes a die, a cover layer, multiple conductive contacts, and a dielectric protection layer. The cover layer includes a molding layer. The molding layer covers the die yet exposes multiple pads on the die. The conductive contacts are formed on a surface of a molding layer facing a same side as the pads, and the conductive contacts are electrically connected to the pads respectively. The dielectric protection layer partially covers surfaces of the conductive contacts and of the molding layer. The flat package can be easily manufactured, as manufacturing the flat package consumes little time and cost. The flat package is small in its overall size, allowing the flat package to fit into a product for use.

### CROSS-REFERENCE TO RELATED APPLICATION(S)

This application claims the priority benefit of TW application serial No. 112151355 filed on Dec. 28, 2023, the entirety of which is hereby incorporated by reference herein and made a part of the specification.

### BACKGROUND OF THE INVENTION

### 1. Field of the Invention

The present invention relates to a package, more particularly a flat package.

### 2. Description of the Related Art

With reference to FIG. 5, FIG. 5 provides a perspective view of a structure of a conventional flat package. The conventional flat package includes a substrate 200, a die 201, a molding layer 202, a via 203, and a redistribution layer 204. The die 201 is electrically connected to the redistribution layer 204 through the via 203. The via 203 is formed in the molding layer 202, and the redistribution layer 204 is formed on a surface of the molding layer 202.

A manufacturing process of the conventional flat package includes many manufacturing steps. For instance, the manufacturing process at least includes manufacturing steps detailed in FIGS. 6A to 6D. As detailed in FIG. 6A, after encapsulating the dies 201 with the molding layer 202, a metallic covering layer 205 is sputtered on a surface of the molding layer 202. As detailed in FIG. 6B, multiple openings 206 are formed on the molding layer 202 for exposing signal pads on the dies 201. As detailed in FIG. 6C, remaining adhesives in the openings 206 are removed by using plasma. As detailed in FIG. 6D, the metallic covering layer 205 is removed. As such, circuit layouts electrically connecting the dies 201 are formed only by executing the manufacturing steps detailed in FIGS. 6A to 6D. This conventional manufacturing method having at least the steps is rather overly complicated and costly. Furthermore, because the via 203 is formed in the molding layer 202, an overall thickness of the conventional flat package is quite thick, which prevents it from fitting in some electronic products for usage.

### SUMMARY OF THE INVENTION

To improve upon the prior arts, the present invention provides a flat package.

The flat package of the present invention includes:
a die, having an active surface and a back surface opposite to the active surface; wherein multiple pads are formed on the active surface of the die;
a cover layer, covering the die without covering the pads on the active surface of the die; wherein a first surface of the cover layer faces a same side as the active surface of the die, and a second surface of the cover layer faces a same side as the back surface of the die;
multiple conductive contacts, formed on the first surface of the cover layer; wherein the conductive contacts electrically contact the pads of the die respectively;
a dielectric protection layer, partially covering surfaces of the conductive contacts.

In comparison with a conventional package, the flat package of the present invention omits forming vias in a molding layer, and by having pads of a die electrically connecting to conductive contacts on a surface through relatively shorter conductive pathways, the present invention is able to decrease an overall thickness of the flat package, and thus miniaturizing the flat package used in a product, allowing the product to also decrease in size. The flat package of the present invention can be easily manufactured, as manufacturing the flat package consumes little time and cost.

### BRIEF DESCRIPTION OF THE DRAWINGS

FIGS. 1A to 1I are flow charts for a first embodiment of a manufacturing method of the present invention.

FIG. 2A is a cross-sectional perspective view for an embodiment of a flat package of the present invention that is made by the first embodiment of the manufacturing method.

FIG. 2B is a cross-sectional perspective view for another embodiment of the flat package of the present invention that is made by the first embodiment of the manufacturing method.

FIGS. 3A to 3J are flow charts for a second embodiment of the manufacturing method of the present invention.

FIG. 4A is a cross-sectional perspective view for an embodiment of the flat package of the present invention that is made by the second embodiment of the manufacturing method.

FIG. 4B is a cross-sectional perspective view for another embodiment of the flat package of the present invention that is made by the second embodiment of the manufacturing method.

FIG. 5 is a perspective view of a structure of a conventional flat package.

FIGS. 6A to 6D are flow charts of parts of a manufacturing method for manufacturing the conventional flat package.

### DETAILED DESCRIPTION OF THE INVENTION

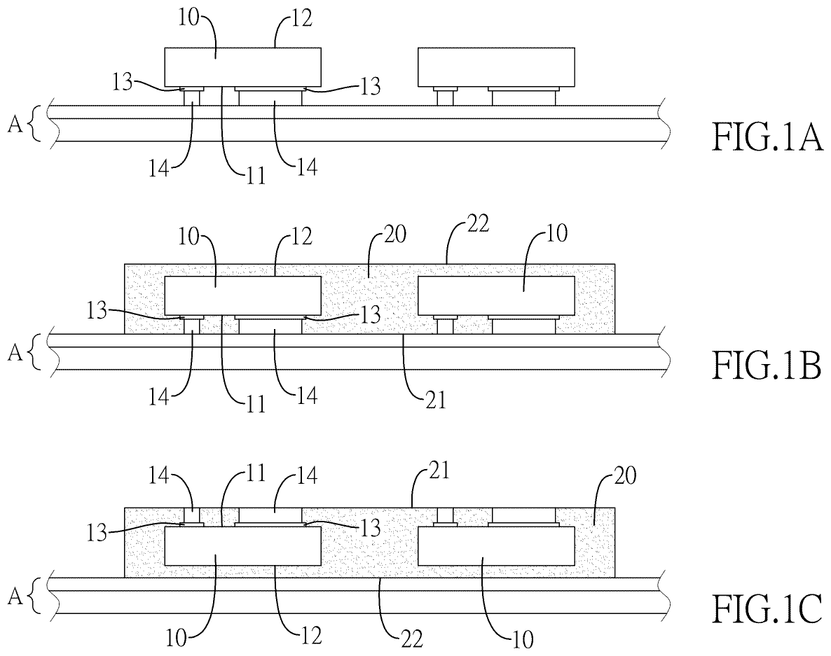

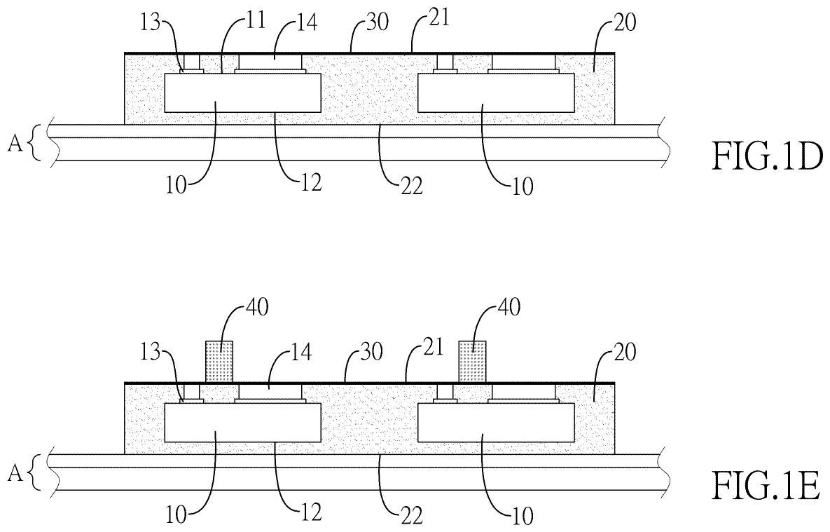

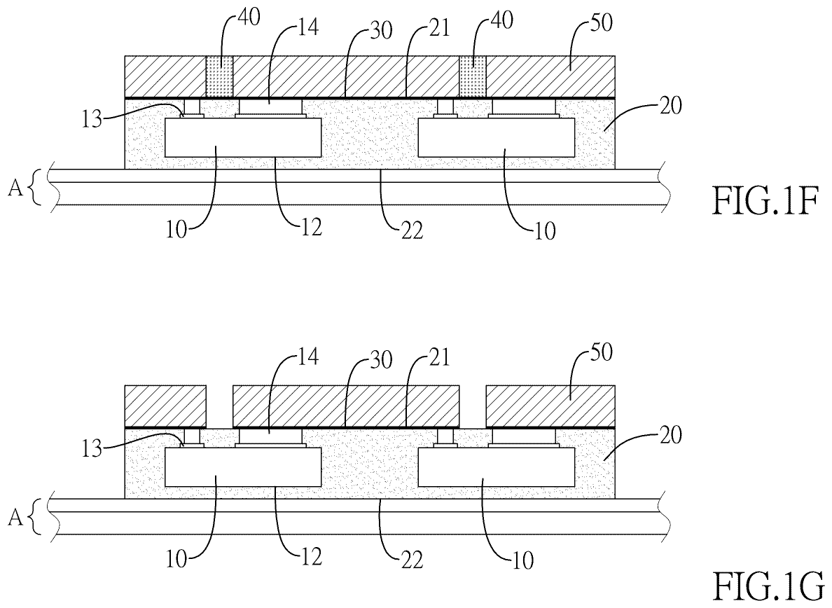

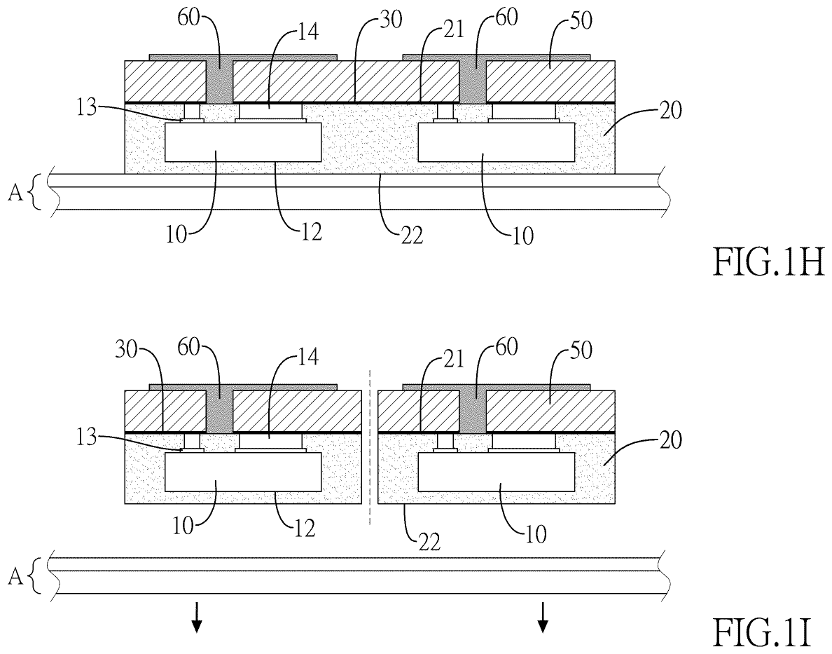

With reference to FIGS. 1A to 1I, an embodiment of a manufacturing method of the present invention is shown. With reference to FIG. 1A, multiple dies 10 are temporarily attached to a carrying tape A. A surface of the carrying tape A is adhesive which allows the dies 10 to be mounted on the carrying tape A. Each of the dies 10 has an active surface 11 and a back surface 12 opposite to the active surface 11. Multiple pads 13 used for electric connections are formed on the active surface 11 of each of the dies 10. When attaching the dies 10, the active surfaces 11 of the dies 10 face down toward the carrying tape A in order to be attached on the carrying tape A. In other embodiments, if heights of the pads 13 of the dies 10 are incompatible, a conductive pillar 14 may first be pre-formed on a surface of each of the pads 13. The conductive pillars 14 may be made of copper, and when bonding the dies 10, a surface of each of the conductive pillars 14 attaches to the carrying tape A.

With reference to FIG. 1B, after die bonding, a molding layer 20 is formed to cover each of the dies 10, more particularly, the molding layer 20 covers the back surface 12 of each of the dies 10. Furthermore, a first surface 21 is defined to be a surface of the molding layer 20 facing a same side as the active surface 11 of each of the dies 10, and a second surface 22 is defined to be another surface of the molding layer 20 facing a same side as the back surface 12 of each of the dies 10. The molding layer 20 is made of materials including but not limited to polypropylene (PP), Ajinomoto build-up film (ABF), Taiwan build-up film (TBF), and epoxy molding compound (EMC), etc. Once the dies 10 are covered by the molding layer 20, each of the dies 10 is held in place and protected by the molding layer 20, allowing each of the dies 10 to be more conveniently processed in subsequent packaging steps.

With reference to FIG. 1C, after the molding layer 20 is formed, the molding layer 20 is flipped and the second surface 22 of the molding layer 20 is temporarily attached to the carrying tape A. After flipping the molding layer 20, the pads 13 or the conductive pillars 14 of the dies 10 are exposed, allowing the active surfaces 11 of the dies 10 to be conveniently modified.

With reference to FIG. 1D, the first surface 21 of the molding layer 20 is covered by a seed layer 30 made of metallic materials, for example, titanium/copper. The seed layer 30 is electrically in contact with the pads 13 or the conductive pillars 14 of the dies 10.

With reference to FIG. 1E, a circuit covering layer 40 is formed on a surface of the seed layer 30. Patterns on the circuit covering layer 40 are used to define positions of conductive contacts of the packages. In the present embodiment, positions covered by the circuit covering layer 40 are not used to form circuits in subsequent manufacturing steps.

With reference to FIG. 1F, a conduction layer is formed on surface areas of the seed layer 30 exposed from the circuit covering layer 40. Furthermore, multiple conductive contacts 50 are formed as the conduction layer electrically connects to the pads 13 of the dies 10. In an embodiment, the conductive layer is formed by electroplating or sputtering, and the conductive layer is made of copper or other types of metal alloys.

With reference to FIG. 1G, once the conductive contacts 50 are formed, the circuit covering layer 40 is removed. Furthermore, parts of the seed layer 30 covered by the circuit covering layer 40 are removed through means such as etching. As the said parts of the seed layer 30 are removed, the conductive contacts 50 are each electrically insulated from one another, and thus the conductive contacts 50 are each independent from one another.

With reference to FIG. 1H, a dielectric protection layer 60 is formed on the first surface 21 of the molding layer 20, and the dielectric protection layer 60 offers protections to each of the conductive contacts 50 by partially covering surfaces of each of the conductive contacts 50. The dielectric protection layer 60 may be a solder mask, a polyimide film, or made of other types of dielectric materials. Once the dielectric protection layer 60 is formed, the packages are separated by dicing along default dicing lanes. Once diced, a side surface of each of the conductive contacts 50 formed by the conductive layer is exposed, and these side surfaces are aligned with a side surface of the molding layer 20.

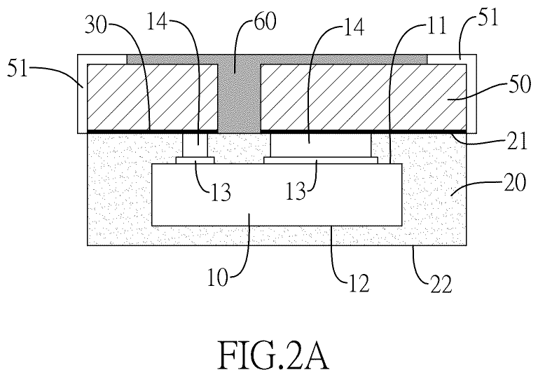

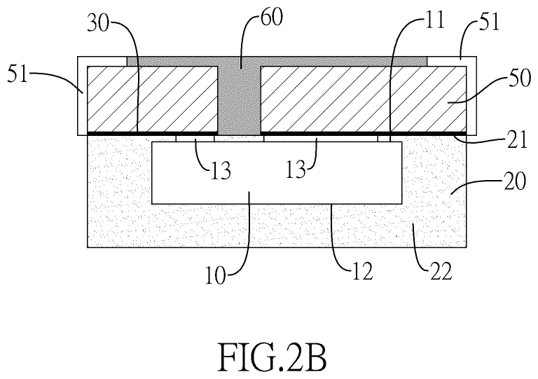

With reference to FIG. 1I and FIG. 2A, surfaces of the conductive contacts 50 that are exposed from the dielectric protection layer 60 are surface processed to form a contact protection layer 51. The contact protection layer 51 covers the side surface of each of the conductive contacts 50. For example, the contact protection layer 51 is a tin layer that is formed on an exposing surface of the conductive contacts 50 by electroless nickel immersion gold (ENIG), electroless nickel/electroless palladium/immersion gold (ENEPIG), electroplating, or any other types of known methods. Once the contact protection layer 51 is formed, the carrying tape A may be removed for creating multiple flat packages that are independent from each other.

According to the manufacturing method mentioned above, a flat package of the present invention is shown in FIG. 2A as an embodiment and shown in FIG. 2B as another embodiment. In either embodiment, the flat package of the present invention includes:
a die 10, having an active surface 11 and a back surface 12 opposite to the active surface 11; wherein multiple pads 13 are formed on the active surface 11 of the die 10;
a cover layer, covering the die 10; wherein in some embodiments, the cover layer includes a molding layer 20, the molding layer 20 exposes the pads 13 on the active surface 11 of the die 10; wherein a first surface 21 of the molding layer 20 faces a same side as the active surface 11 of the die 10, and a second surface of the molding layer 20 faces a same side as the back surface 12 of the die 10;
multiple conductive contacts 50, formed on a surface of the cover layer, in other words, formed on the first surface 21 of the molding layer 20; wherein the conductive contacts 50 electrically contact the pads 13 respectively;
a dielectric protection layer 60, partially covering surfaces of the conductive contacts 50; wherein the conductive contacts 50 exposed from the dielectric protection layer 60 are contacts of the flat package that are available for external electrical connections, and furthermore, a contact protection layer 51 can form on each surface of the conductive contacts 50 exposed from the dielectric protection layer 60.

With reference to FIG. 2A, multiple conductive pillars 14 are respectively formed on the pads 13. The conductive contacts 50 are indirectly and electrically connected to the pads 13 through the conductive pillars 14. Terminal surfaces of the conductive pillars 14 are flat and aligned. The terminal surfaces of the conductive pillars 14 are flush with the first surface 21 of the molding layer 20. Within the molding layer 20, each of the conductive pillars 14 stretches straight without any turns. As such, the terminal surfaces of the conductive pillars 14 are in direct and flat contact with the surfaces of the conductive contacts 50.

With reference to FIG. 2B, the conductive contacts 50 are directly and electrically connected to the surfaces of the pads 13.

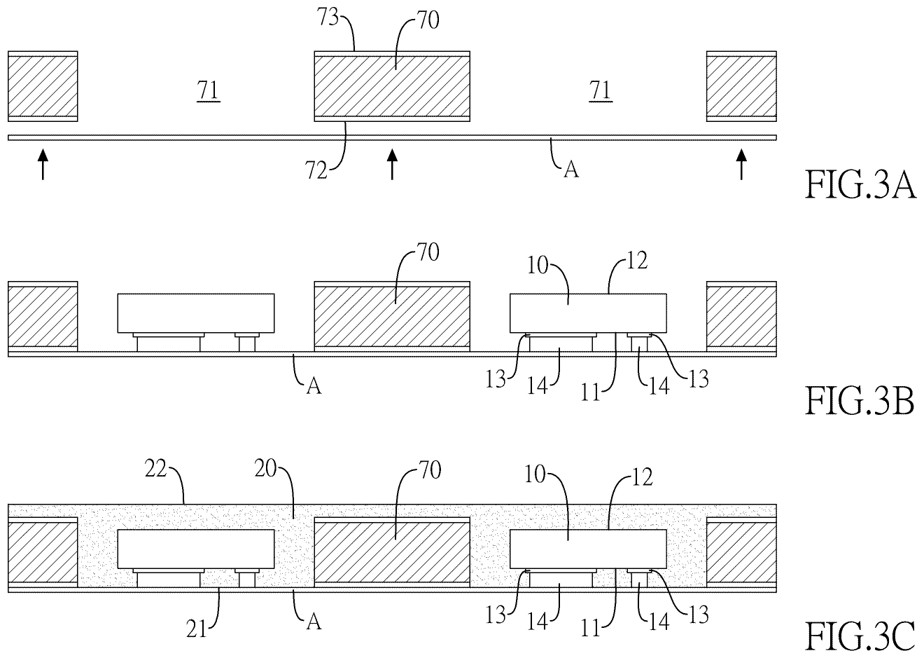

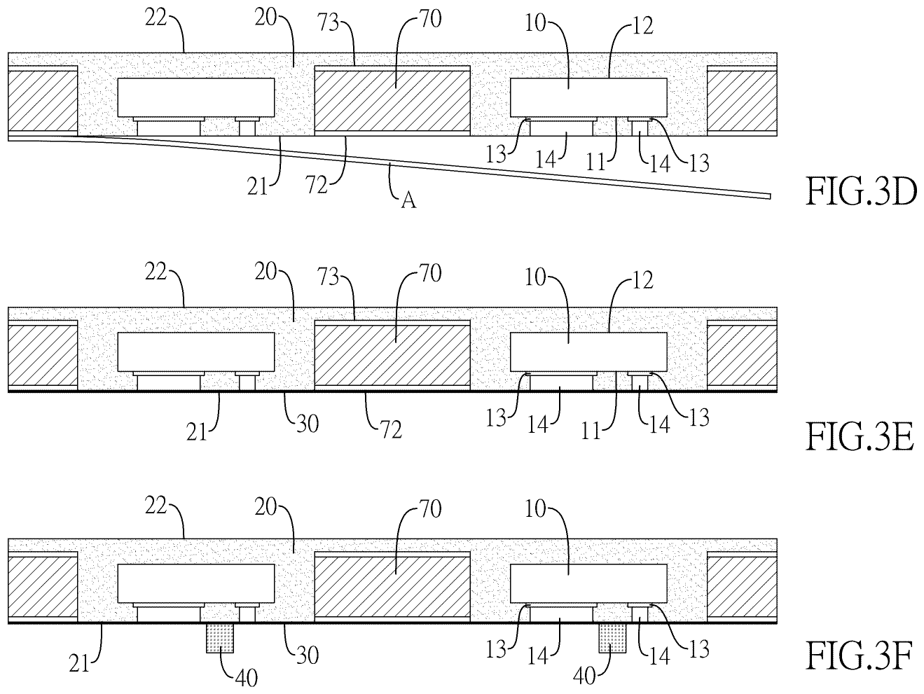

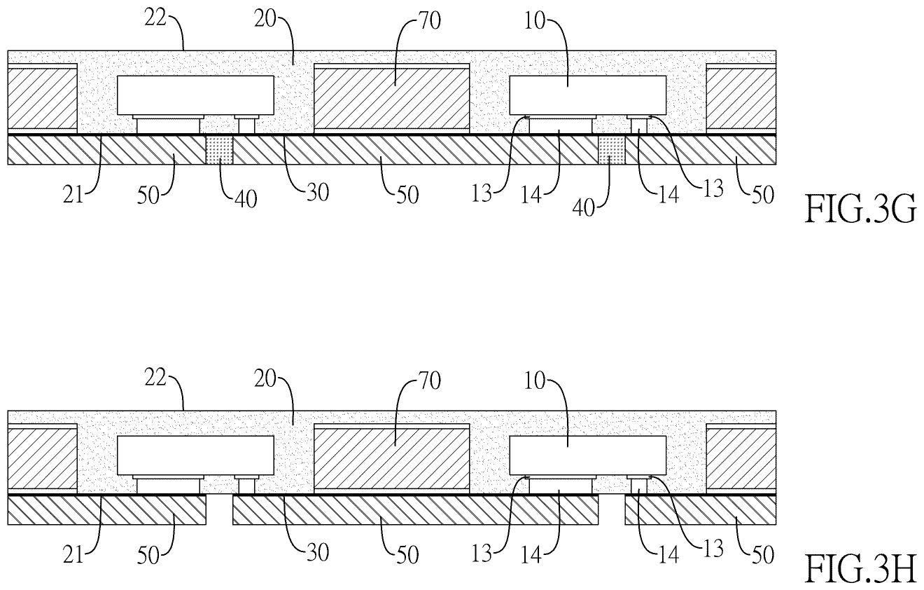

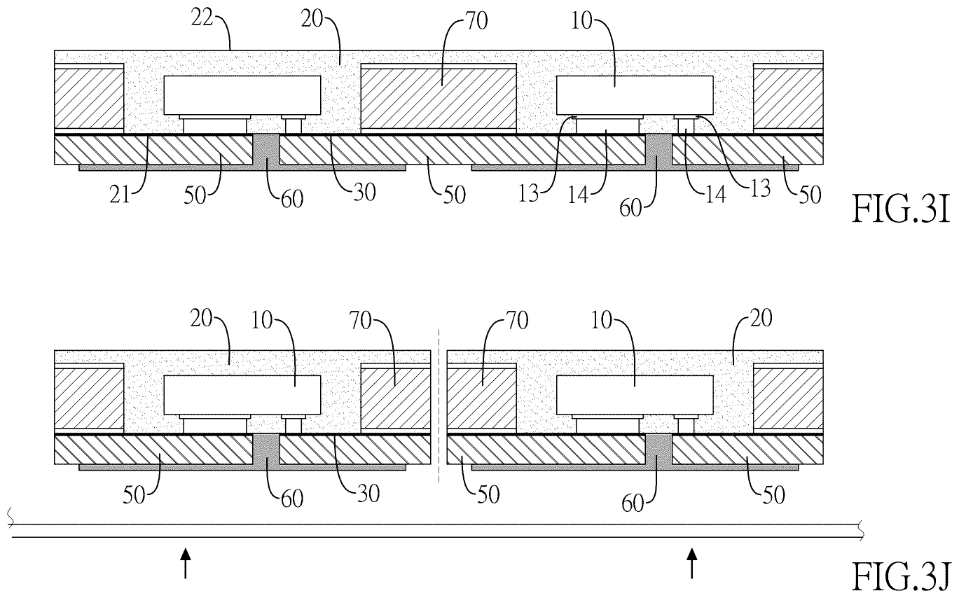

With reference to FIGS. 3A to 3J, another embodiment of the manufacturing method of the present invention is shown. With reference to FIG. 3A, multiple storage spaces 71 are formed on a substrate 70. The substrate 70 may be an insulator layer, or a copper clad laminate (CCL) that has copper clads respectively laminated on opposite surfaces of an insulating main body. The substrate 70 has a front surface 72 and a rear surface 73. A carrying tape A is temporarily attached to the rear surface 73 of the substrate 70, and the carrying tape A is adhesive.

With reference to FIG. 3B, the active surfaces 11 of the dies 10 face down toward the carrying tape A and attach on the carrying tape A as the dies 10 are mounted in the carrying spaces 71. A height of each of the dies 10 may be substantially equal to a thickness of the substrate 70. In the present embodiment, a conductive pillar 14 may first be pre-formed on a surface of each pad 13, and a surface of each of the conductive pillars 14 attaches to the carrying tape A. In some other embodiments, the pads 13 of the dies 10 may also be directly mounted on the carrying tape A without forming the conductive pillars 14.

With reference to FIG. 3C, after bonding the die 10, a molding layer 20 is formed to cover each of the dies 10 and a surface of the substrate 70. The molding layer 20 completely fills in the carrying spaces 71, and the molding layer 20 also covers a back surface 12 of each of the dies 10. Furthermore, a first surface 21 is defined to be a surface of the molding layer 20 facing a same side as the active surface 11 of each of the dies 10, and a second surface 22 is defined to be another surface of the molding layer 20 facing a same side as the back surface 12 of each of the dies 10. The molding layer 20 is made of materials including but not limited to polypropylene (PP), Ajinomoto build-up film (ABF), Taiwan build-up film (TBF), and epoxy molding compound (EMC), etc. Once the dies 10 are covered by the molding layer 20, each of the dies 10 is held in place and protected by the molding layer 20 and the substrate 70, allowing each of the dies 10 to be more conveniently processed in subsequent packaging steps.

With reference to FIGS. 3D and 3E, after removing the carrying tape A, the pads 13 or the conductive pillars 14 of the dies 10, as well as the first surface 21 of the molding layer 20 are exposed. The first surface 21 of the molding layer 20 and the rear surface 73 of the substrate 70 are then covered by a seed layer 30 made of metallic materials, for example, titanium/copper. The seed layer 30 is electrically in contact with the pads 13 or the conductive pillars 14 of the dies 10.

With reference to FIG. 3F, a circuit covering layer 40 is formed on a surface of the seed layer 30. Patterns on the circuit covering layer 40 are used to define positions of conductive contacts of packages. In the present embodiment, positions covered by the circuit covering layer 40 are not used to form circuits in subsequent manufacturing steps.

With reference to FIG. 3G, a conduction layer is formed on surface areas of the seed layer 30 exposed from the circuit covering layer 40. Furthermore, multiple conductive contacts 50 are formed as the conduction layer electrically connects to the pads 13 of the dies 10. In an embodiment, the conductive layer is formed by electroplating or sputtering, and the conductive layer is made of copper or other types of metal alloys.

With reference to FIG. 3H, once the conductive contacts 50 are formed, the circuit covering layer 40 is removed. Furthermore, parts of the seed layer 30 covered by the circuit covering layer 40 are removed through means such as etching. As the said parts of the seed layer 30 are removed, the conductive contacts 50 are each electrically insulated from one another, and thus the conductive contacts 50 are each independent from one another.

With reference to FIG. 3I, a dielectric protection layer 60 is formed to protect the conductive contacts 50 by partially covering surfaces of the conductive contacts 50. The dielectric protection layer 60 may be a solder mask, a polyimide film, or made of other types of dielectric materials. Once the dielectric protection layer 60 is formed, the packages are separated by dicing.

With reference to FIG. 3J, another carrying tape is temporarily attached to a surface of the dielectric protection layer 60, and furthermore, the packages are separated by dicing around each of the packages.

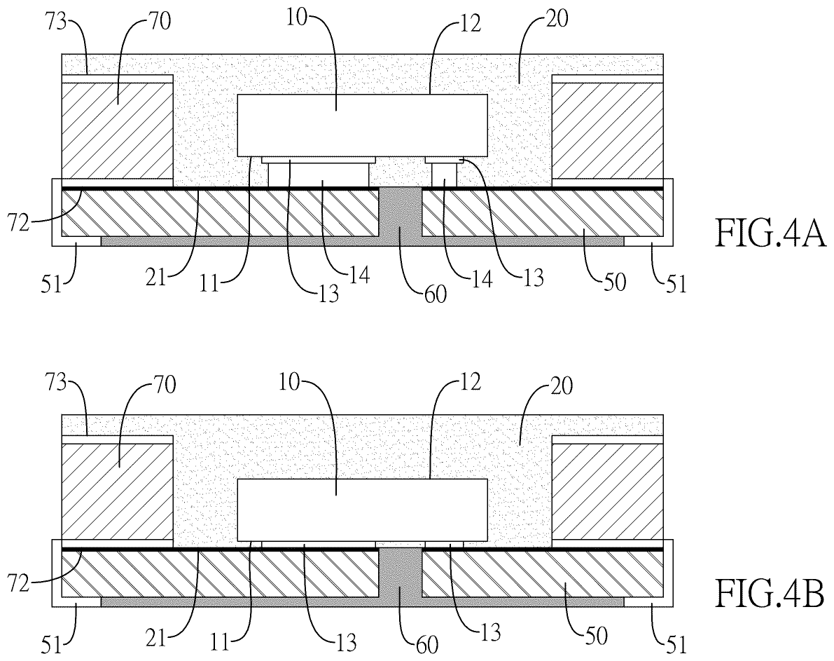

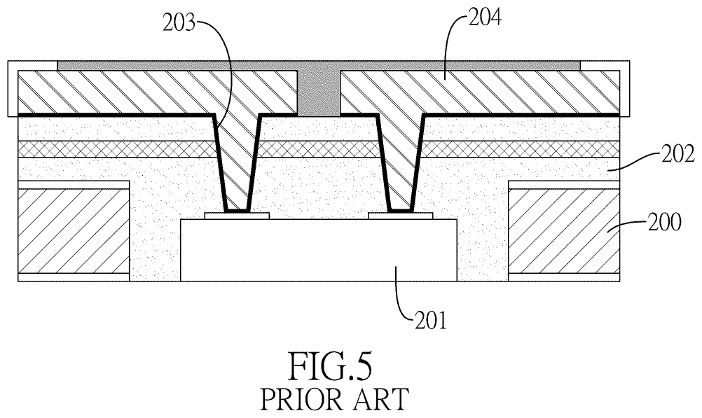

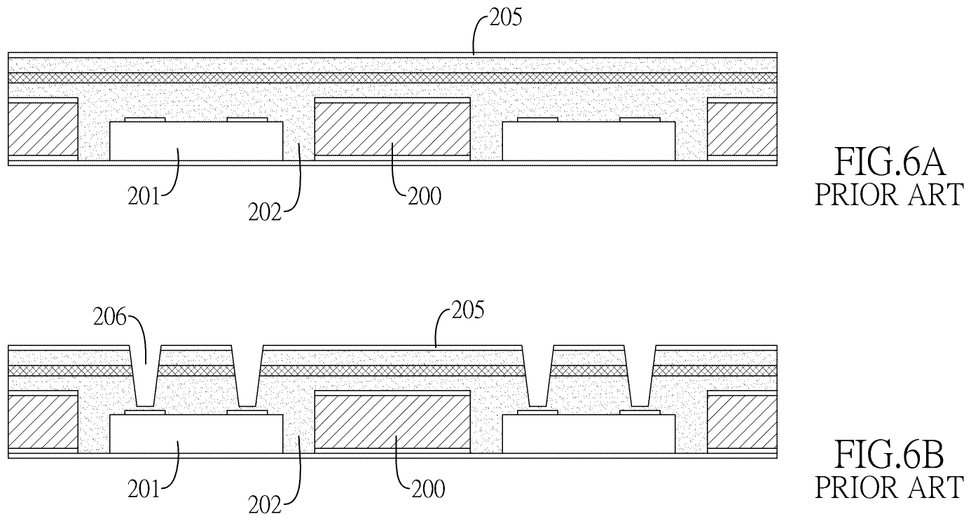

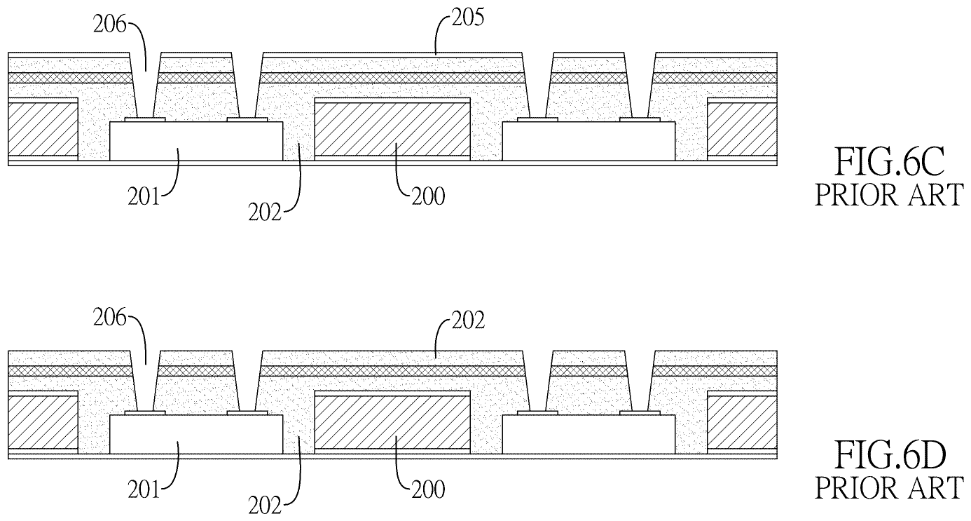

Surfaces of the conductive contacts 50 that are exposed from the dielectric protection layer 60 are surface processed to form into a contact protection layer as shown in FIG. 4A. For example, the contact protection layer 51 is a tin layer that is formed on an exposing surface of the conductive contacts 50 by electroless nickel immersion gold (ENIG), electroless nickel/electroless palladium/immersion gold (ENEPIG), electroplating, or any other types of known methods.

According to a second embodiment of the manufacturing method mentioned above, a flat package of the present invention is shown in FIG. 4A as an embodiment and shown in FIG. 4B as another embodiment. In either embodiment, the flat package of the present invention includes:
a die 10, having an active surface 11 and a back surface 12 opposite to the active surface 11; wherein multiple pads 13 are formed on the active surface 11 of the die 10; wherein the active surface 11 of the die 10 faces a same side as a front surface 72 of a substrate 70, and the back surface 12 of the dies faces a same side as a rear surface 73 of the substrate 70;
a cover layer, covering the die 10; wherein in some embodiments, the cover layer includes a molding layer 20 and the substrate 70; wherein the substrate 70 includes a storage space 71, and the die 10 is mounted in the storage space 71; wherein the substrate 70 has the front surface 72 and the rear surface 73 facing opposite directions; wherein the front surface 72 of the substrate 70 faces a same side as the active surface 11 of the die 10, and the rear surface 73 of the substrate 70 faces a same side as the back surface 12 of the die 10; wherein the molding layer 20 is filled in the storage space 71, and the molding layer 20 covers the back surface 12 of the die 10 and the rear surface 73 of the substrate 70; wherein the molding layer 20 exposes the pads 13 on the active surface 11 of the die 10; wherein a first surface 21 of the molding layer 20 faces a same side as the active surface 11 of the die 10, and a second surface 22 of the molding layer 20 faces a same side as the back surface 12 of the die 10;
multiple conductive contacts 50, formed on a surface of the cover layer, in other words, formed on the first surface 21 of the molding layer 20 and the front surface 72 of the substrate 70; wherein the conductive contacts 50 electrically contact the pads 13 respectively;
a dielectric protection layer 60, partially covering surfaces of the conductive contacts 50; wherein the conductive contacts 50 exposed from the dielectric protection layer 60 are contacts of the flat package that are available for external electrical connections, and furthermore, a contact protection layer 51 can form on each surface of the conductive contacts 50 exposed from the dielectric protection layer 60.

With reference to FIG. 4A, multiple conductive pillars 14 are respectively formed on the pads 13. The conductive contacts 50 are indirectly and electrically connected to the pads 13 through the conductive pillars 14. Terminal surfaces of the conductive pillars 14 are flat and aligned. The terminal surfaces of the conductive pillars 14 are flush with the first surface 21 of the molding layer 20.

With reference to FIG. 4B, the conductive contacts 50 are directly and electrically connected to the surfaces of the pads 13. The first surface 21 of the molding layer 20 is flush with the pads 13 of the dies 10.

In comparison to prior arts, the manufacturing method of the present invention for manufacturing flat packages avoids a need to form a metallic covering layer on a surface of a molding layer, a need to form openings corresponding to signal pads of dies on a molding layer, a need to cleanse the opening with plasma, and a need to remove the metallic covering layer, etc. As such, the present invention simplifies manufacturing steps, decreases time consumption, decreases manufacturing cost, and decreases energy expenses required for manufacturing a flat package.

What is claimed is:

1. A flat package, comprising:
a die, having an active surface and a back surface opposite to the active surface; wherein multiple pads are formed on the active surface of the die;
a cover layer, covering the die without covering the pads on the active surface of the die; wherein a first surface of the cover layer faces a same side as the active surface of the die, and a second surface of the cover layer faces a same side as the back surface of the die;
multiple conductive contacts, formed on the first surface of the cover layer; wherein the conductive contacts electrically contact the pads of the die respectively;
a dielectric protection layer, partially covering surfaces of the conductive contacts.

2. The flat package as claimed in claim 1, wherein the cover layer is a molding layer;
wherein a first surface of the molding layer faces a same side as the active surface of the die, and a second surface of the molding layer faces a same side as the back surface of the die.

3. The flat package as claimed in claim 1, wherein the cover layer comprises:
a substrate, having a storage space for mounting the die therein; wherein a front surface of the substrate faces a same side as the active surface of the die, and a rear surface of the substrate faces a same side as the back surface of the die;
a molding layer, filled in the storage space, and covering the back surface of the die and the rear surface of the substrate;
wherein the molding layer exposes the pads on the active surface of the die;
wherein a first surface of the molding layer faces a same side as the active surface of the die, and a second surface of the molding layer faces a same side as the back surface of the die.

4. The flat package as claimed in claim 2, wherein a conductive pillar is formed on each of the pads of the die;
wherein the conductive contacts electrically contact the pads of the die respectively.

5. The flat package as claimed in claim 3, wherein a conductive pillar is formed on each of the pads of the die;
wherein the conductive contacts electrically contact the pads of the die respectively.

6. The flat package as claimed in claim 1, wherein a contact protection layer is formed on a surface of each of the conductive contacts exposed from the dielectric protection layer.

7. The flat package as claimed in claim 2, wherein a contact protection layer is formed on a surface of each of the conductive contacts exposed from the dielectric protection layer.

8. The flat package as claimed in claim 3, wherein a contact protection layer is formed on a surface of each of the conductive contacts exposed from the dielectric protection layer.

9. The flat package as claimed in claim 2, wherein the pads of the die are flush with the first surface of the molding layer.

10. The flat package as claimed in claim 3, wherein the pads of the die are flush with the first surface of the molding layer.

11. The flat package as claimed in claim 4, wherein terminal surfaces of the conductive pillars are flush with the first surface of the molding layer.

12. The flat package as claimed in claim 5, wherein terminal surfaces of the conductive pillars are flush with the first surface of the molding layer.
